(19) United States
(12) Patent Application Publication
(10) Pub. No.: US 2012/0314164 A1
(43) Pub. Date: Dec. 13, 2012

(54) COLOR FILTER SUBSTRATE, LIQUID CRYSTAL DISPLAY PANEL, AND METHOD FOR PRODUCING COLOR FILTER SUBSTRATE

(75) Inventor: Tetsuroh Suyama, Osaka (JP)

(73) Assignee: SHARP KABUSHIKI KAISHA, Osaka (JP)

(21) Appl. No.: 13/575,541

(22) PCT Filed: Dec. 13, 2010
(86) PCT No.: PCT/JP2010/072320

§ 371 Date: Jul. 26, 2012

(30) Foreign Application Priority Data
Jan. 29, 2010 (JP) 2010-017780

(51) Int. Cl. G02F 1/1335; H05K 13/00

(52) U.S. Cl. 349/106; 427/58

(57) ABSTRACT

Disclosed is a color filter substrate that is capable of keeping the distance from a TFT substrate constant by using a black matrix. Electrical leakage is not likely to occur between the color filter substrate and the TFT substrate even when a foreign substance is caught between the color filter substrate and the TFT substrate. Specifically disclosed is a color filter substrate (1) that is used for a liquid crystal display panel having a plurality of pixels arranged in a matrix and that includes: a transparent substrate (2) that has a plurality of recessed portions (21) formed by digging into a surface (23) at positions corresponding to the pixels; a plurality of color filters (3) filled into the recessed portions (21); a transparent conductive film (4) that is formed on the transparent substrate (2) so as to cover the color filters (3) and serves as a common electrode for the pixels; and a nonconductive black matrix (5) that is formed on the transparent conductive film (4) so as to divide the color filters (3) from each other.

### TECHNICAL FIELD

The present invention relates to a color filter substrate used for a liquid crystal display panel and the like.

### BACKGROUND ART

A liquid crystal display panel employed in a display of televisions, cellular phones, and the like includes a pair of two substrates that face each other through a liquid crystal layer. Of those substrates, one substrate is a thin film transistor substrate containing a glass substrate on which thin film transistors (referred to as “TFTs” hereinafter) as active devices and pixel electrodes are respectively arranged in a matrix. The other substrate is a color filter substrate (referred to as “CF” substrate hereinafter) containing a glass substrate on which color filters of red (R), green (G) and blue (B), an opposite electrode (common electrode), and the like are formed.

FIG. 5 is an explanatory illustration to schematically indicate a diagrammatic structure of a conventional liquid crystal display panel 9P. FIG. 5 shows a cross-section view of a part of the liquid crystal display panel 9P. The liquid crystal display panel 9P is equipped with a liquid crystal layer 7P, a TFT substrate 8P, and a CF substrate 1P that faces the TFT substrate 8P through the liquid crystal layer 7P. The conventional CF substrate 1P, as shown in FIG. 5, is equipped with a glass substrate 2P, a plurality of color filters 3P that are formed on the glass substrate 2, a light-shielding black matrix 5P formed on the glass substrate 2P so as to partition each of the color filters 3P, columnar spacers (which are also called photo spacers) 6P that are made of photoresist and formed on the black matrix 5P, and a transparent conductive film (common electrode) 4P that is made of ITO or the like formed to cover the color filters 3P, the black matrix 5P, and the spacers 6P. In addition, an alignment film (not shown in the figure) is formed on a surface of the transparent conductive film 4P to align liquid crystal compounds in the liquid crystal layer 7P to a prescribed direction.

The CF substrate 1P is bonded to the TFT substrate 8P through the liquid crystal layer 7P by a sealant or the like that is not shown in the figure.

In the CF substrate 1P, when the thickness (height from the surface of the glass substrate 2P) of each of the color filters 3P (31P, 32P, 33P) is increased to improve color reproducibility and the like, the thickness (height from the surface of the glass substrate 2P) of the black matrix 5P that surrounds and partitions each of the color filters needs to be set to the substantially same thickness (height) as each of color filters. Further, on the black matrix 5P having the thickness determined in this manner, the spacers 6P are formed to secure the distance “d” (which is also referred to as “cell gaps” as seen in FIG. 5) between the TFT substrate 8P and the CF substrate 1P.

The CF substrate 1P has protrusions toward the TFT substrate 8P at portions 11P where the respective spacers 6P are arranged. On the other hand, the TFT substrate 8P has portions 81P that protrude toward the portions 11P of the CF substrate 1P. In the protruding portions 81P of the TFT substrate 8P, not-shown gate lines, source lines, and the like are placed.

The spacers 6P maintain respective cell gaps “d” of the liquid crystal display panel 9P uniform so as to prevent display non-uniformity and the like that are caused by uneven cell gaps “d” of the liquid crystal display panel 9P.

Since insulating materials such as alignment films or the like respectively cover the outermost layers of the protruding portions 11P of the CF substrate 1P and the protruding portions 81P of the TFT substrate 8P, generally, these portions are not electrically connected.

Patent Document 1 discloses a CF substrate containing color filters embedded in a plurality of recessed portions formed on a surface of a glass substrate. A black matrix in Patent Document 1 is formed on the glass substrate so that the height thereof becomes the same as that of the color filters embedded in the glass substrate.

### RELATED ART DOCUMENTS

### Patent Documents

Patent Document 1: Japanese Patent Application Laid-Open Publication No. H6-308312

### SUMMARY OF THE INVENTION

### Problems to be Solved by the Invention

In a manufacturing process of the liquid crystal display panel 9P such as a process of bonding the CF substrate 1P to the TFT substrate 8P and the like, a small quantity of foreign substances such as metal powder and the like may be mixed into the liquid crystal layer 7P. The origin of such foreign substances, for instance, can be found in debris of manufacturing jigs made of metal (SUS, for instance) used in the manufacturing process and the like.

If the foreign substance size is small enough compared to the cell gaps “d” of the liquid crystal display panel 8P, even when the foreign substance is present in an opening 12P of the CF substrate 1P where the color filters 3P are formed, for instance, it is unlikely that the foreign substance adversely affects display quality of the liquid crystal display panel 9P.

However, such a small foreign substance, which does not cause a problem in the opening 12, may cause a problem when the foreign substance is present in the areas where the protruding portions 11P of the CF substrate 1P contact the protruding portions 81P of the TFT substrate 8P, and is sandwiched therebetween, which results in an electrical leakage between them. It is understood that when the foreign substance is interposed between those portions, the surface of the protruding portions 11P of the CF substrate 1P and the surface of the protruding portions 81P of the TFT substrate 8P are damaged, and the transparent conductive film, gate lines, or the like are exposed from such portions. Then, the foreign substance allows electricity to flow between the gate line of the TFT substrate 8P and the transparent conductive film (common electrode) 4P of the CF substrate 1P and the like, resulting in the aforementioned leakage. When such a leakage occurs, a linear (or streak-like) display defect starting from the leakage point will appear in the liquid crystal panel 9P.

The leakage described above also occurs in a CF substrate that is configured in the manner disclosed in Patent Document 1, thereby causing a problem.

The conventional color filter substrate 1P has the spacers 6P formed on the black matrix 5P so as to secure the cell gaps “d” as shown in FIG. 5. Therefore, the cell gaps “d” are affected not only by variations in thickness (height) of the spacers 6P, but also variations in thickness (height) of the black matrix 5P. Thus, in order to maintain the cell gaps “d” in a uniformed manner, both of the thickness (height) of the spacers 6P and the thickness (height) of the black matrix 5P need to be controlled.

The present invention is aiming at, in a liquid crystal display panel and the like equipped with a TFT substrate and a color filter substrate that face each other through a liquid crystal layer, providing a color filter substrate that suppresses electric leakage between the substrate and the TFT substrate even when a foreign substance is interposed between these substrates and that can maintain a prescribed distance from the TFT substrate, and providing a manufacturing method and the like of such a color filter substrate.

A color filter substrate according to the present invention is characterized as follows.

1. A color filter substrate employed for a liquid crystal display panel that includes a plurality of matrix-arrayed pixels, the color filter substrate including: a transparent substrate that has a plurality of recessed portions formed by digging a surface of the transparent substrate so as to correspond to respective pixels; a plurality of color filters filled in the respective recessed portions; a transparent conductive film formed on the transparent substrate to cover each of the color filters and used as a common electrode for each of the pixels; and a non-conductive black matrix formed on the transparent conductive film to partition the respective color filters.

2. The black matrix is made of a resin black matrix.

3. The transparent conductive film is substantially parallel to the surface of the transparent substrate.

4. A liquid crystal display panel according to the present invention includes the color filter substrate according to any one of 1 to 3 above.

5. A manufacturing method of a color filter substrate according to the present invention is a method for manufacturing a color filter substrate that is employed in a liquid crystal display panel having a plurality of matrix-arrayed pixels and that is equipped with: a transparent substrate having a plurality of recessed portions formed by digging a surface of the transparent substrate so as to correspond to the respective pixels; a plurality of color filters filled in the respective recessed portions; a transparent conductive film formed on the transparent substrate to cover each of the color filters and used as a common electrode for each of the pixels; and a non-conductive black matrix formed on the transparent conductive film to partition the respective color filters, the manufacturing method including: a first resist pattern forming step of forming a first photoresist layer on a surface of a transparent plate, performing exposure on the first photoresist layer through a first photo mask having a pattern corresponding to the respective pixels, and developing the first photoresist layer after the exposure so as to form a first resist pattern on the transparent plate; a recessed portion forming step of forming the transparent substrate by digging the transparent plate through etching using the resist pattern as a mask so as to form a plurality of recessed portions on the transparent plate; a color filter forming step of filling color filter resins in the respective recessed portions of the transparent substrate so as to form the color filters in the respective recessed portions; a transparent conductive film forming step of forming the transparent conductive film on the transparent substrate having the color filters filled therein; and a black matrix forming step of forming a photosensitive black resin layer on the transparent conductive film, performing exposure on the photosensitive black resin layer through a second photo mask having a pattern that partitions the respective color filters, and developing the photosensitive black resin layer to form the black matrix on the transparent conductive film after exposure.

### Effects of the Invention

According to a color filter substrate of the present invention, when the substrate is placed to face a TFT substrate through a liquid crystal layer as in a liquid crystal display panel, even if a foreign substance is caught between the color filter substrate and the TFT substrate, electrical leakage between the two can be suppressed. Also, by forming the black matrix on the transparent conductive film that can be planarized with ease, the distances (cell gaps) between the color filter substrate and the TFT substrate can be kept constant.

### BRIEF DESCRIPTION OF THE DRAWINGS

FIG. 1 is an explanatory illustration to schematically indicate a general configuration of a color filter substrate according to an embodiment of the present invention.

FIG. 2 is an explanatory illustration to schematically indicate a manufacturing process of the color filter substrate.

FIG. 3 is an explanatory illustration to schematically indicate a manufacturing process of the color filter substrate following the manufacturing process shown in FIG. 2.

FIG. 4 is an explanatory illustration to schematically indicate another manufacturing process of the color filter substrate following the manufacturing process shown in FIG. 2.

FIG. 5 is an explanatory illustration to schematically indicate a general configuration of a conventional liquid crystal display panel.

### DETAILED DESCRIPTION OF THE INVENTION

A color filter substrate according to an embodiment of the present invention will be explained in detail below with reference to figures. It should be noted, however, that the present invention is not limited to the embodiment described in this specification as an example.

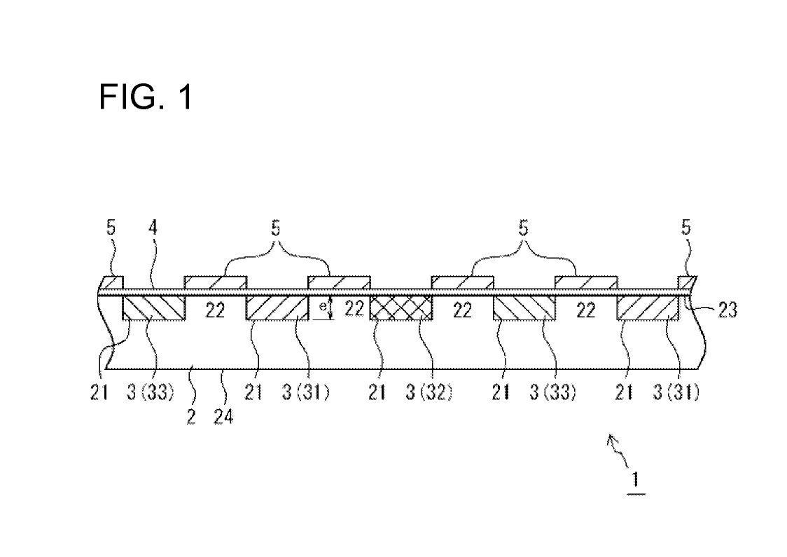

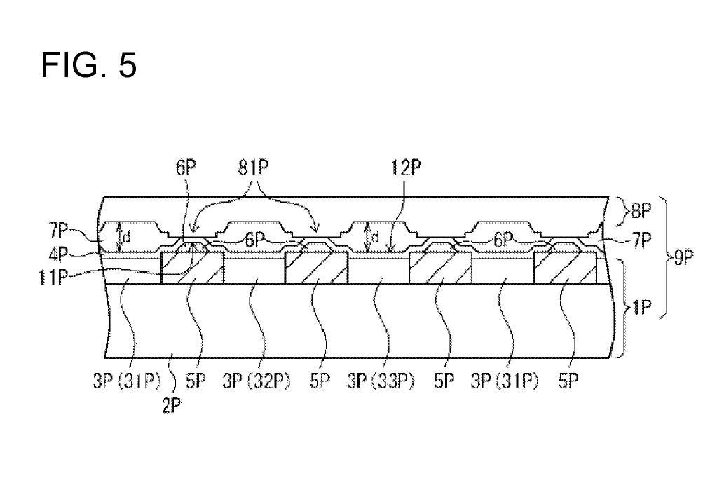

FIG. 1 is an explanatory illustration to schematically indicate a general configuration of a color filter substrate 1 according to an embodiment. As shown in FIG. 1, the color filter substrate 1 is equipped with a transparent substrate 2, color filters 3, a transparent conductive film 4, and a black matrix 5. This color filter substrate 1 can be used in place of the color filter substrate 1P of the conventional liquid crystal display panel 9P shown in FIG. 5. A liquid crystal display panel using this color filter substrate 1 includes a plurality of matrix-arrayed pixels in the same manner as the conventional panel. As the pattern of the matrix array, various known matrices such as stripe matrix, delta matrix, mosaic matrix can be used.

The transparent substrate 2 is a substrate made of glass (glass substrate), for instance, and is equipped with a plurality of recessed portions 21 on a surface 23 thereof. The respective recessed portions 21 are formed by scraping and digging the surface 23 at prescribed positions by using a known etching process such as glass etching, for instance. Positions of the respective recessed portions 21 are set so as to correspond to a plurality of matrix-arrayed pixels in the liquid crystal display panel. The depth “e” of the recessed portions 21 is appropriately set according to the thickness of the color filters 3 filled in the recessed portions 21 and the like. Protruding portions 22, which are the surface of the transparent substrate 2 that have not been dug, remain between the respective recessed portions 21. The protruding portions 22 are arranged in a substantially grid pattern so as to surround the respective recessed portions 21 in a plan view of the transparent substrate 2 from the side of the surface 23. In the present specification, the transparent substrate 2 before the recessed portions 21 are formed on the surface 23 may be referred to as a transparent plate 20 for explanation purposes.

The color filters 3 are made of several filters that transmit mutually different colors, and are made of three color filters of a red (R) color filter 31, a blue (B) color filter 32 and a green (G) color filter 33, for example. In the present embodiment, one set of these three color filters 3 (31, 32, 33) is used for a single picture element. The color filters 3 of the respective colors are filled and arranged in order in the respective recessed portions 21.

As the color filters 3, known materials can be used. The color filters 3 are made of films that are obtained by coloring a resin material with red, green and blue dyes, films that are obtained by dispersing red, green and blue pigments in a resin material, multiple interference films using inorganic substances, or the like, for instance. The color filters 3 are filled in the respective recessed portions 21 of the transparent substrate 2 by using an ink-jet feeding apparatus, for instance. When the feeding apparatus is used, materials for the color filters 3 are prepared as liquid materials obtained by dispersing and dissolving the materials in solvents such as organic solvent solutions. This liquid material is injected in each of the recessed portions 21 of the transparent substrate 2 by using the feeding apparatus. The liquid material injected and filled in each of the recessed portions 21 is thereafter dried in a baking process and the like to obtain the film-shaped color filters 3.

It is preferable that injection amount of the raw material for the color filters 3 in each of the recessed portions 21 be set such that upper surfaces of the color filters 3 becomes as high as the surface 23 of the transparent substrate 2. Here, overflown portions of the color filters 3 and the like from each of the recessed portions 21 may be appropriately removed by polishing using a polishing tape and the like.

It is preferable that upper surfaces of the color filters 3 filled in the respective recessed portions 21 be flat. Moreover, it is preferable that difference in level between the upper surfaces of the color filters 3 and the surface 23 of the transparent substrate 2 (surface 23 of the protruding portions 22) be eliminated. In other words, it is preferable that the surface 23 of the transparent substrate 2 with the color filters 3 embedded therein be flat as a whole. As described above, when the surface 23 of the transparent substrate 2 is flat as a whole, it becomes easier to form the transparent conductive film 4 having a uniform thickness and a flat surface on the transparent substrate 2.

The transparent conductive film 4 is used as a common electrode (opposite electrode) of the color filter substrate 1. The transparent conductive film 4 is formed on the surface 23 of the transparent substrate 2, which has had the color filters 3 embedded in the respective recessed portions 21, so as to cover the surfaces of the color filters 3. The transparent conductive film 4 faces a plurality of pixel electrodes (not shown in figures) formed in a matrix on the TFT substrate, and is used as a common electrode on the side of the color filter substrate 1 for each pixel.

Known low resistive and high light transmissive films, such as ITO (Indium Tin Oxide) film, IZO (Indium Zinc Oxide), and the like, can be used for the transparent conductive film 4. An ITO film is formed on the transparent substrate 2 by using a known film formation method such as a sputtering method or the like, for instance. The transparent conductive film 4 may be made of a single layer or multiple layers. Other layers such as a base layer may be formed under the transparent conductive film 4.

The black matrix 5 is made of a light-shielding film formed on the surface 23 of the protruding portions 22 formed in a grid pattern on the transparent substrate 2. This black matrix 5 is placed on the transparent conductive film 4 so as to partition the respective color filters 3 in a plan view of the transparent substrate 2 from the side of the surface 23. The black matrix 5 blocks light emitted from a backlight apparatus (not shown in figures) in a direction from the surface 23 (the TFT substrate) to the rear surface 24 such that the light does not leak from areas (surface 23 of the protruding portions 22) of the transparent substrate 2 where the color filters 3 are not formed.

In addition to the function similar to that of the conventional black matrix as described above, the black matrix 5 according to the present embodiment also serves as a spacer to maintain constant distances (cell gaps) from the TFT substrate (see the spacers 6P shown in FIG. 5). For this reason, it is preferable that the black matrix 5 be made of a material that has not only light-shielding property, but also a sufficient strength as a spacer and non-conductive property. The black matrix 5 is made of a resin material in which a black pigment such as titan black is dispersed (so-called a resin black matrix), for instance. Conductivity of the black matrix 5 made of such a material is low enough compared to the transparent conductive film 5 made of an ITO film or the like, for instance, and therefore, the black matrix 5 can be regarded as non-conductive in the present specification. The thickness of the black matrix 5 is appropriately set in view of an OD value and cell gaps of the liquid crystal display panel and the like. In the present embodiment, it is preferable that the thickness of the black matrix 5 (height from the surface of the transparent conductive film 4) be set to be substantially uniform so as to make the cell gaps of the liquid crystal display panel uniform.

The black matrix 5 is formed by dropping a liquid material that is obtained by dispersing and dissolving materials in a solvent such as an organic solvent on the surface 23 of the protruding portions 22 of the transparent substrate 2 by using an ink-jet feeding apparatus, and by thereafter performing a baking process, for instance. The black matrix 5 may also be formed on the transparent substrate 2 by processing a photosensitive black resin or the like by the photolithography technology.

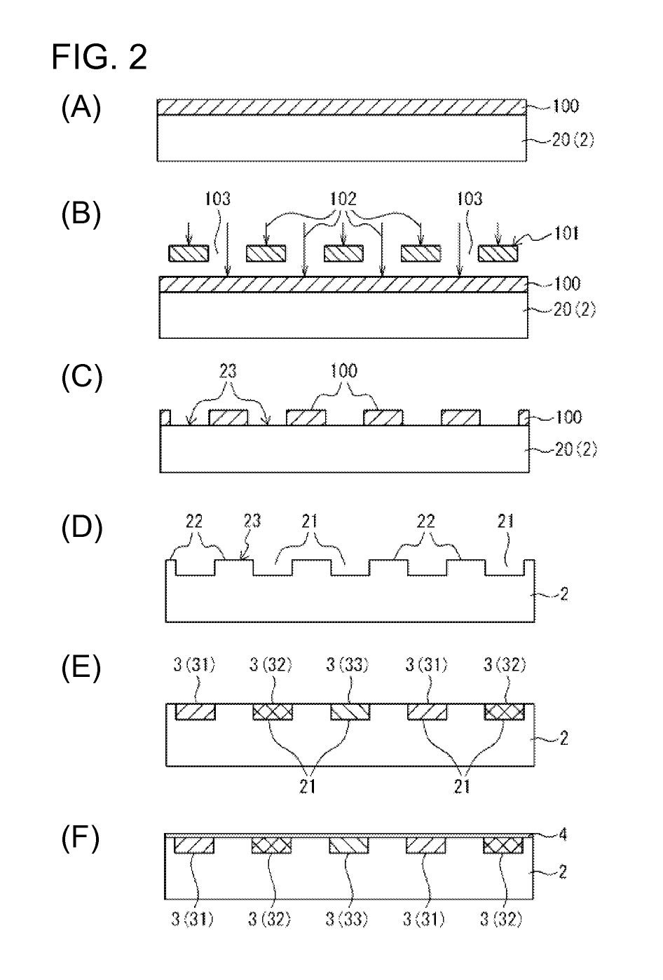

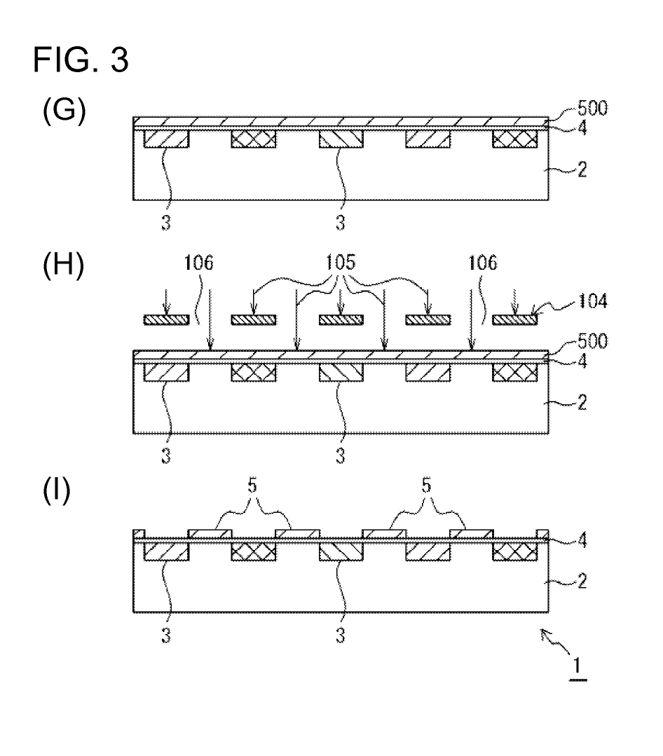

A manufacturing method of the color filter substrate 1 will be explained below with reference to FIGS. 2 and 3. FIG. 2 is an explanatory illustration to schematically indicate the manufacturing process of the color filter substrate 1. FIG. 3 is an explanatory illustration to schematically indicate another manufacturing process of the color filter substrate 1 following the manufacturing process shown in FIG. 2. FIG. 2A is an explanatory illustration to schematically indicate a step of forming a photoresist layer 100 on the transparent plate 20. FIG. 2B is an explanatory illustration to schematically indicate a step of performing exposure on the photoresist layer 100 formed on the transparent plate 20 through a photo mask 101. FIG. 2C is an explanatory illustration to schematically indicate a step of developing the exposed photoresist layer 100. FIG. 2D is an explanatory illustration to schematically indicate a step of forming the recessed portions 21 by etching the surface of the transparent plate 20. FIG. 2E is an explanatory illustration to schematically indicate a step of filling the color filters 3 in the recessed portions 23. FIG. 2F is an explanatory illustration to schematically indicate a step of forming the transparent conductive film 4 on the transparent substrate 2. FIG. 3G is an explanatory illustration to schematically indicate a step of developing a photosensitive black resin layer 500 on the transparent conductive film 4. FIG. 3H is an explanatory illustration to schematically indicate a step of performing exposure on the photosensitive black resin layer 500 through a photo mask 104. FIG. 3I is an explanatory illustration to schematically indicate a step of developing the exposed photosensitive black resin layer 500.

As shown in FIG. 2A, a glass substrate is prepared as the transparent plate 20 (transparent substrate 2). On the surface of the glass substrate, a negative type photoresist layer (first photoresist layer) 100 is formed by using a coating apparatus (not shown in figures) such as a slit coater.

Next, as shown in FIG. 2B, light (ultraviolet light, for instance) 102 is radiated to the photoresist layer 100 through a photo mask (a first photo mask) 101 to expose the photoresist layer 100. The photo mask 101 is made of a light-shielding plate material, and has a pattern of openings 103, which corresponds to the respective pixels of the liquid crystal display panel. Areas of the photoresist layer 100 where the light 102 was radiated (exposed areas) are cured, while unexposed areas of the photoresist layer 100 are not cured.

As shown in FIG. 2C, when the exposed photoresist layer 100 is developed with a liquid developer, the unexposed areas are removed, and the exposed areas of the photoresist layer 100 remain on the transparent plate 20.

When the transparent plate 2 is etched by using the developed photoresist layer 100 as a mask, the surface 23 is dug, and as a result, as shown in FIG. 2D, the transparent substrate 2 having a plurality of the recessed portions 21 in the surface 23 thereof is obtained. The photoresist layer 100 left after etching is removed appropriately.

Next, as shown in FIG. 2E, the color filters 3 (31, 32, 33) of the respective colors are filled in the respective recessed portions 21 of the transparent substrate 2. Liquid materials of the respective colors are injected into the respective recessed portions 21 in order by using an ink-jet feeding apparatus (not shown in figures). Thereafter, the liquid materials in the respective recessed portions 21 are baked and dried, thereby forming the color filters 3 (31, 32, 33) made of films of the respective liquid materials in the corresponding recessed portions 21 of the transparent substrate 2.

Next, as shown in FIG. 2F, a transparent conductive film 4 made of an ITO film is formed by using a known film formation method such as a sputtering method on the transparent substrate 2 having the color filters 3 formed thereon. The transparent conductive film 4 is formed on the transparent substrate 2 so as to cover the surfaces of the color filters 3. A annealing treatment or the like may be appropriately applied to the transparent conductive film 4 made of the ITO film or the like.

As shown in FIG. 3G, a photosensitive black resin layer 500 is formed on the transparent conductive film 4 by using a coating apparatus (not shown in figures) such as a slit coater. This photosensitive black resin is of a negative type, and conventional materials for black matrix can be used. In other embodiments, the photosensitive black resin layer may be formed by attaching a black resist that has been formed in a film shape in advance to the transparent conductive film 4.

Next, as shown in FIG. 3H, light (ultraviolet light, for instance) 105 is radiated to the photosensitive black resin layer 500 formed on the transparent conductive film 4 through a photo mask 104 (second photo mask) to expose the photosensitive black resin layer 500. The photo mask 104 is made of a light-shielding plate material, and has a pattern of openings 106 that partitions the respective color filters 3 formed on the transparent substrate 2. The areas of the photosensitive black resin layer 500 where the light 105 was radiated are cured while unexposed areas of the photoresist layer 100 are not cured.

As shown in FIG. 3I, when the exposed photosensitive black resin layer 500 is developed with a liquid developer, the unexposed areas are removed, and the black matrix 5 is formed on the transparent conductive film 4. This way, the color filter substrate 1 of this embodiment is manufactured.

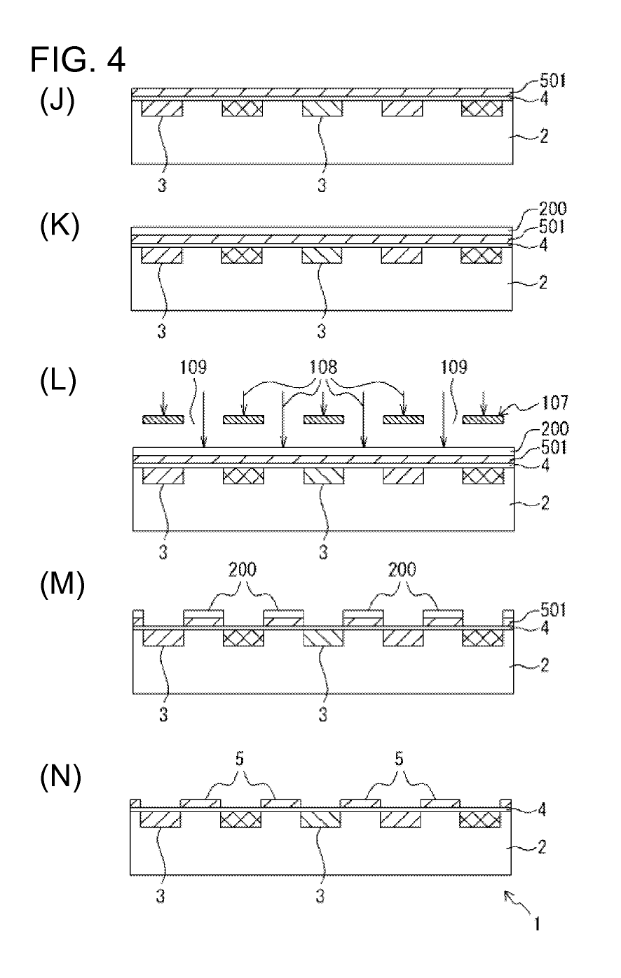

Another manufacturing method of the color filter substrate 1 will be explained below with reference to FIG. 4. FIG. 4 is an explanatory illustration to schematically indicate another manufacturing process of the color filter substrate 1 following the manufacturing process shown in FIG. 2. FIG. 4J is an explanatory illustration to schematically indicate a step of forming a developable black resin layer 501 on the transparent conductive film 4. FIG. 4K is an explanatory illustration to schematically indicate a step of forming a positive type photoresist layer 200 on the black resin layer 501. FIG. 4L is an explanatory illustration to schematically indicate a step of exposing the photoresist layer 200 on the black resin layer 501 through a photo mask 107. FIG. 4M is an explanatory illustration to schematically indicate a step of developing the exposed photoresist layer and the black resin layer 501 at once, and FIG. 4N is an explanatory illustration to schematically indicate a step of performing a heat treatment to the developed black resin layer 501, and thereafter removing the photoresist layer 200 left on the black resin layer 501.

As shown in FIG. 4J, the developable black resin layer 501 is formed on the transparent conductive film 4 by using a coating apparatus (not shown in figures) such as a slit coater. This black resin is made of a material used for conventional black matrix. In other embodiments, the black resin layer may be formed by attaching the black resist that has been formed in a film shape in advance to the transparent conductive film 4.

Next, as shown in FIG. 4K, the positive type photoresist layer 200 is formed on the black resin layer 501 by using a coating apparatus (not shown in figures) such as a slit coater.

Next, as shown in FIG. 4L, light 108 (ultra violet light, for instance) is radiated to the photoresist layer 200 through the photo mask 107 to expose the photoresist layer 200. The photo mask 107 is made of a light-shielding plate material, and has a pattern of openings 109 that partitions the respective color filters 3 formed on the transparent substrate 2. The areas of the photoresist layer 200 where the light 108 was radiated become more soluble to a liquid developer.

After the photoresist layer 200 is exposed, a heat treatment is conducted to the black resin layer 501 formed on the transparent substrate 2 so as to cross-link and cure the black resin layer 501. Next, when the photoresist layer 200 and the black resin layer 500 are developed with a liquid developer, as shown in FIG. 4M, the exposed areas of the photoresist layer 200 and the black resin layer 500 thereunder are removed at once.

Thereafter, as shown in FIG. 4N, the resist layer 200 left on the black resin layer 501 is removed, and the black matrix 5 is formed on the transparent conductive film 4. The color filter substrate 1 may also be manufactured by forming the black matrix 5 on the transparent conductive film 4 in the manner described above.

The color filter substrate 1 of this embodiment may be manufactured by methods other than indicated in FIGS. 2 to 4. A not-shown alignment film is formed on the surfaces of the transparent conductive film 4 and the black matrix 5 of the color filter substrate 1. A polarizing plate (not shown in figures), optical films (not shown in figures), and the like are appropriately layered on the rear surface 24 of the color filter substrate 1. The color filter substrate 1 according to the present embodiment is bonded to the TFT substrate 8P shown in FIG. 5 through the liquid crystal layer 7P, and is used as a substrate for a liquid crystal display panel.

In the color filter substrate 1 according to the present embodiment shown in FIG. 1, the color filters 3 are embedded in the recessed portions 21 of the transparent substrate 2, and are covered with the transparent conductive film 4. Further, the black matrix 5 is arranged on the transparent conductive film 4. In other words, the black matrix 5 becomes the highest portion of the color filter substrate 1, which allows the black matrix 5 to serve as a spacer to adjust distances (cell gaps) from the TFT substrate.

The transparent conductive film 4 made of an ITO film and the like can be very thin, and the surface thereof can be planarized with ease as compared with the black matrix 5P and the like of the conventional color filter substrate 1P shown in FIG. 5. Since the black matrix 5 is formed on such a transparent conductive film 4, the aforementioned distances (cell gaps) of the liquid crystal display panel including the color filter substrate 1 according to the present embodiments can be controlled mainly by the thickness of the black matrix 5 alone, and can be thereby made uniform with ease. Therefore, it becomes possible to stabilize the display quality of the aforementioned liquid crystal display panel with ease.

Further, in the color filter substrate 1 according to the present embodiments, the black matrix 5 is non-conductive, and the thickness thereof is generally greater than that of an alignment film. As a result, in comparison with the conventional color filter substrate 1P and the like, the color filter substrate 1 according to the present embodiment has a structure in which electric leakage with the TFT substrate is less likely to occur even when foreign substances are interposed between the TFT substrate and the color filter substrate 1.

Moreover, in the color filter substrate 1 according to the present embodiment, the thickness (height from the surface of the transparent conductive film 4) of the black matrix 5 can be set in a wider range and with a greater degree of freedom. Thus, if needed, by adjusting the thickness of the black matrix 5, the color filter substrate 1 can be placed closer to the TFT substrate (cell gaps “d” can be made smaller) than the conventional liquid crystal display panel 9P shown in FIG. 5 and the like. The liquid crystal display panel in which the color filter substrate 1 is placed near the TFT substrate can improve electric capacitance of each pixel as compared with the conventional liquid crystal display panel 9P shown in FIG. 5 and the like, which allows for improvement of display response speed (driving speed).

Further, in other embodiments, spherical or columnar spacers may be provided on the black matrix 5 indicated in FIG. 1. The color filter substrate may be bonded to the TFT substrate with the aforementioned spacers interposed therebetween.

1. A color filter substrate employed for a liquid crystal display panel that includes a plurality of matrix-arrayed pixels, the color filter substrate comprising:
a transparent substrate that has a plurality of recessed portions formed by digging a surface of the transparent substrate so as to correspond to the respective pixels;
a plurality of color filters filled in the respective recessed portions;
a transparent conductive film formed on the transparent substrate to cover each of the color filters as a common electrode for each of the pixels; and
a non-conductive black matrix formed on the transparent conductive film to partition the respective color filters.

2. The color filter substrate according to claim 1, wherein the black matrix is made of a resin black matrix.

3. The color filter substrate according to claim 1, wherein the transparent conductive film is substantially in parallel with the surface of the transparent substrate.

4. A liquid crystal display panel including a TFT substrate, a color filter substrate, and a liquid crystal layer, the TFT substrate and the color filter substrate being disposed to face each other through the liquid crystal layer, wherein the TFT substrate includes a transparent substrate on which thin film transistors and pixel electrodes are formed in a matrix, and
wherein the color filter substrate comprises:
a transparent substrate that has a plurality of recessed portions formed by digging a surface of the transparent substrate so as to correspond to the respective pixels of the TFT substrate;
a plurality of color filters filled in the respective recessed portions;
a transparent conductive film formed on the transparent substrate to cover each of the color filters as a common electrode for each of the pixels; and
a non-conductive black matrix formed on the transparent conductive film to partition each of the color filters.

5. The liquid crystal display panel according to claim 4, wherein the black matrix formed on the color filter substrate is made of a resin black matrix.

6. The liquid crystal display panel according to claim 4, wherein the transparent conductive film formed on the color filter substrate is substantially in parallel with the surface of the transparent substrate.

7. A method for manufacturing a color filter substrate employed in a liquid crystal display panel having a plurality of matrix-arrayed pixels, the color filter substrate including: a transparent substrate having a plurality of recessed portions formed by digging a surface of the transparent substrate so as to correspond to the respective pixels; a plurality of color filters filled in the respective recessed portions; a transparent conductive film formed on the transparent substrate to cover each of the color filters as a common electrode for each of the pixels; and a nonconductive black matrix formed on the transparent conductive film to partition the respective color filters, the method comprising:
a first resist pattern forming step of forming a first photoresist layer on a surface of a transparent plate, exposing the first photoresist layer through a first photo mask having a pattern corresponding to the respective pixels, and developing the first photoresist layer after exposure so as to form a first resist pattern on the transparent plate;
a recessed portion forming step of obtaining a transparent substrate by digging the transparent plate through etching using the resist pattern as a mask so as to form a plurality of recessed portions on the transparent plate;
a color filter forming step of filling color filter resins in the respective recessed portions of the transparent substrate so as to form the color filters in the respective recessed portions;
a transparent conductive film forming process of forming the transparent conductive film on the transparent substrate having the color filters filled therein; and
a black matrix forming step of a black matrix on the transparent conductive film after exposure.

8. The method according to claim 7, wherein the black matrix forming step includes:
forming a photosensitive black resin layer on the transparent conductive film;
exposing the photosensitive black resin layer through a second photo mask having a pattern that corresponds to the color filters; and
developing the photosensitive black resin layer to form the black matrix on the transparent conductive film after exposure.

9. The method according to claim 7, wherein the black matrix forming step includes:
forming a black resin layer on the transparent conductive film
forming a photoresist layer on the black resin layer;
exposing the photoresist layer through a second photo mask; and
developing the black resin layer and the black resin layer at once to form the black matrix on the transparent conductive film after exposure.
